(19) United States
(12) Patent Application Publication
(10) Pub. No.: US 2012/0229980 A1
(43) Pub. Date: Sep. 13, 2012

(54) HEAT DISSIPATION DEVICE

(75) Inventor: XIANG-WEN KUANG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/117,152

(22) Filed: May 27, 2011

(30) Foreign Application Priority Data
Mar. 9, 2011 (CN) 201110056205.8

(51) Int. Cl. H05K 7/20

(52) U.S. Cl. 361/697; 361/704; 361/720

(57) ABSTRACT

A heat dissipation device includes a base for being contacted with a heat-generating element mounted on a circuit board, two frames rotatably mounted to the base, and a thermal module secured to the base. A slot is defined in each frame for allowing a fastener to extend through to engage in the circuit board.

### BACKGROUND

1. Technical Field

The present disclosure relates to a heat dissipation device for circuit boards.

2. Description of Related Art

Heat sinks used as cooling elements in computers usually can only be fixed to circuit boards whose fixing holes are arranged in a particular manner, which is less desirable in cases that elements have been mounted to circuit boards whose fixing holes have a different arrangement.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is an exploded, isometric view of an exemplary embodiment of a heat dissipation device.

FIG. 2 is an assembled, isometric view of FIG. 1.

FIG. 3 is a use state view of FIG. 2.

FIG. 4 is similar to FIG. 3, but shows another state of use.

### DETAILED DESCRIPTION

The disclosure, including the accompanying drawings, is illustrated by way of example and not by way of limitation. It should be noted that references to “an” or “one” embodiment in this disclosure are not necessarily to the same embodiment, and such references mean at least one.

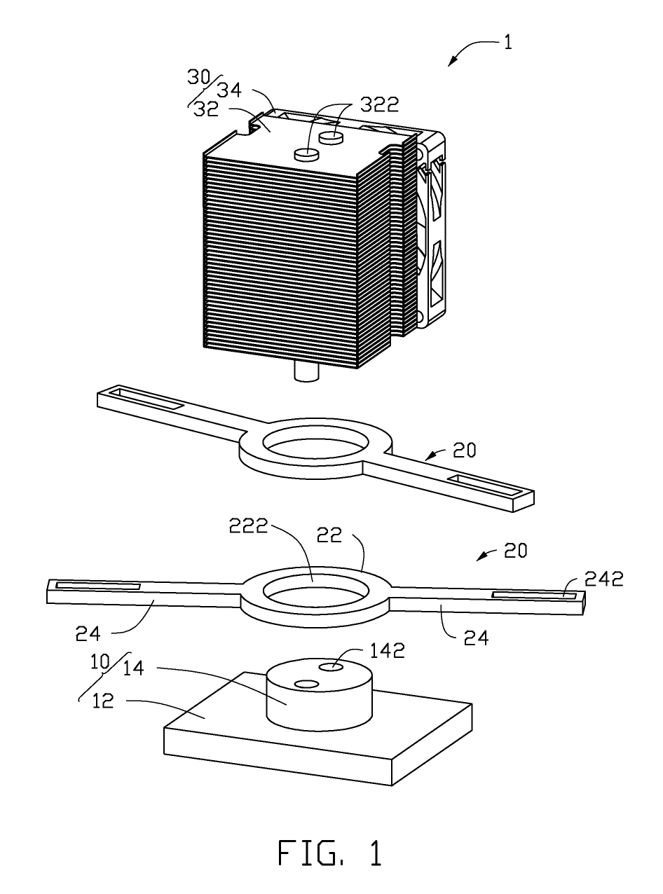

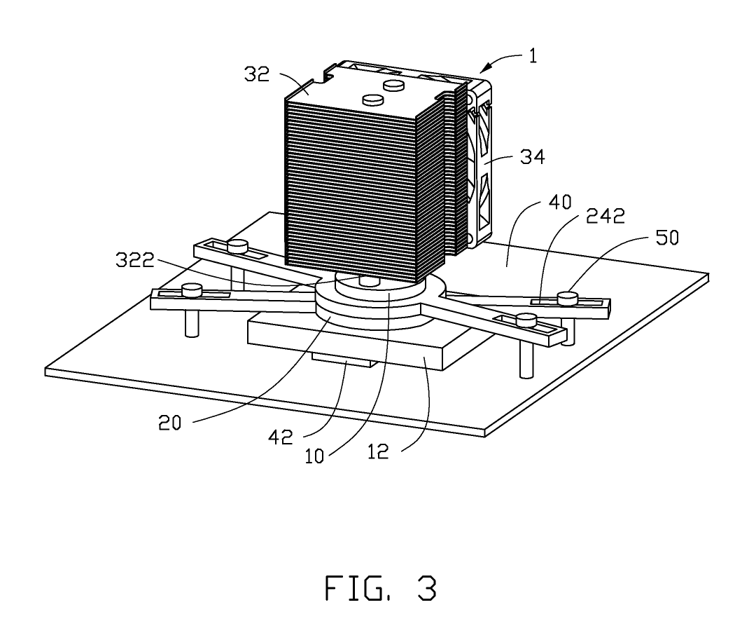

Referring to FIGS. 1 and 3, an exemplary embodiment of a heat dissipation device includes a thermal base 10, two frames 20, a thermal module 30, and a plurality of fasteners 50.

The base 10 includes a substantially rectangular board 12 and a column-shaped fixing portion 14 perpendicularly extending up from the board 12. The fixing portion 14 defines two fixing holes 142 perpendicular to the board 12, extending through a top of the fixing portion 14 opposite to the board 12.

Each frame 20 includes a circular pivoting portion 22 and two bar-shaped arms 24 extending from opposite sides of the pivoting portion 22. A pivot hole 222 is defined in the pivoting portion 22. A slot 242 is longitudinally defined in each arm 24, opposite to the pivoting portion 22.

The thermal module 30 includes a heat sink 32, two thermal tubes 32 extending through the top and the bottom of the heat sink 32, and a fan 34 is mounted to a side of the heat sink 32.

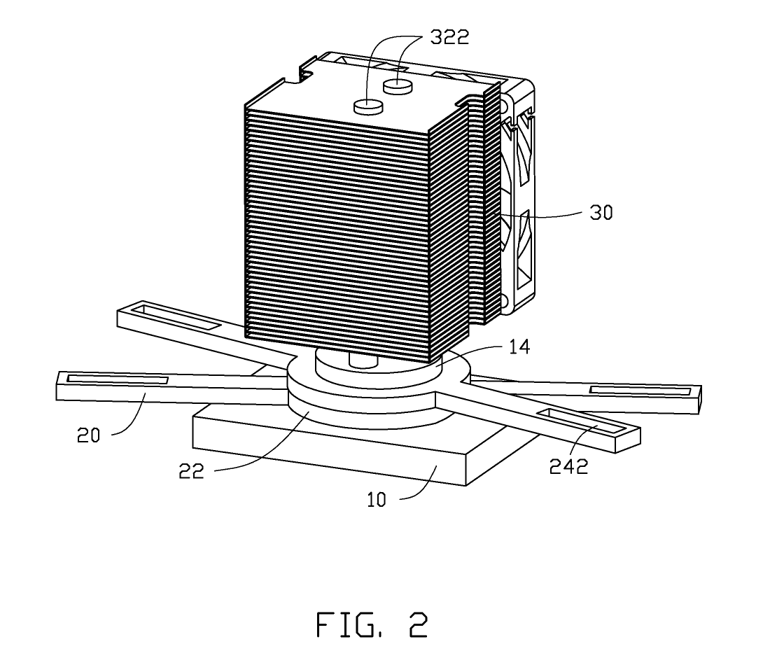

Referring to FIG. 2, in assembly, the pivoting portions 22 are stacked and fit about the fixing portion 14 through the through holes 222. Thereby, the frames 20 are rotatably stacked to the base 10. The thermal tubes 322 are inserted into the fixing holes 142, to mount the thermal module 30 to the base 10.

Referring to FIG. 3, to fix the heat dissipation device 1 to a first circuit board 40 defining a plurality of engaging holes (not shown) for cooling an element 42, the bottom of the board 12 contacts a top of the element 42 to absorb heat from the element 42. The frames 20 are rotated about the fixing portion 14. Thereby, the slots 242 are in alignment with the corresponding engaging holes. The fasteners 50 extend through the slots 242 to engage in the engaging hole, to fix the heat dissipation device 1 to the circuit board 40.

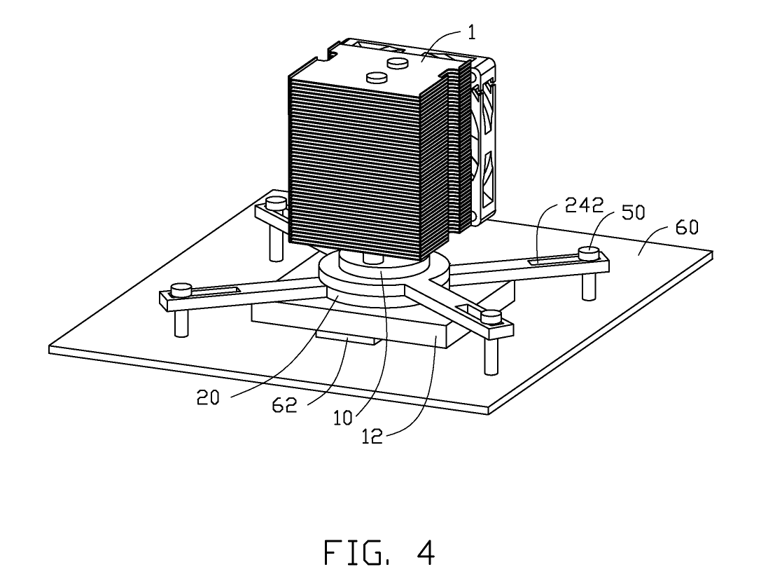

Referring to FIG. 4, to fix the heat dissipation device 1 to a second circuit board 60 for cooling an element 62, the heat dissipation device 1 is fixed to the circuit board 60 the same as it is being fixed to the circuit board 40. Because the engaging holes of the circuit board 60 have different arrangement from the engaging holes of the circuit board 40, the frames 20 are rotated, an angle between the arms 24 of the frames 20 increases, to fit for the arrangement of the engaging holes of the circuit board 60.

The frames 20 can be rotated about the fixing portion 14, and the fasteners 50 can be slid along the slots 242, thereby the heat dissipation device 1 can be fixed to different circuit boards whose engaging holes have different arrangement.

It is believed that the present embodiments and their advantages will be understood from the foregoing description, and they will be apparent that various changes may be made thereto without departing from the spirit and scope of the description or sacrificing all of their material advantages, the examples hereinbefore described merely being exemplary embodiments.

What is claimed is:

1. A heat dissipation device for being mounted on a circuit board with engaging holes, the heat dissipation device comprising:
a thermal base for being attached on the circuit board;
two frames rotatably mounted to the base, each frame defining a slot;
a thermal module mounted to the base; and
a plurality of fasteners, the two frames being configured to rotate to align the slots with the engaging holes such that the fasteners are to extend through the slots to engage in the engaging holes of the circuit board.

2. The heat dissipation device of claim 1, wherein the base comprises a board and a fixing portion protruding up from the board, the frames are pivotably mounted to the fixing portion.

3. The heat dissipation device of claim 2, wherein the fixing portion defines a fixing hole, the thermal module comprises a heat sink and a thermal tube engaging in the fixing hole.

4. The heat dissipation device of claim 3, wherein the thermal module further comprises a fan mounted to the heat sink.

5. The heat dissipation device of claim 3, wherein the thermal tube extends through the heat sink.

6. The heat dissipation device of claim 2, wherein each frame comprises a pivoting portion and two arms extending from opposite sides of the pivoting portion, the pivoting portion defines a pivot hole pivotably fitting about the fixing portion, the slot is defined in each arm.

7. The heat dissipation device of claim 6, wherein the arms are substantially bar-shaped.

8. The heat dissipation device of claim 7, wherein the pivoting portion is substantially circular-shaped

9. An assembly comprising:
a circuit board mounted with a heat-generating element;
a thermal base for being attached on the heat-generating element;
two frames rotatably mounted to the base, each frame defining a plurality of slots;
a thermal module mounted to the base; and
a plurality of fasteners extending through the slots to engage in the circuit board.

10. The assembly of claim 9, wherein the base comprises a board contacting the heat-generating element, and a fixing portion protruding up from the board, each frame is pivotably mounted to the fixing portion.

11. The assembly of claim 10, wherein the fixing portion defines a fixing hole, the thermal module comprises a thermal tube engaging in a fixing hole defined in the fixing portion.

12. The assembly of claim 11, wherein the thermal module further comprises a heat sink through which the thermal tube extends to engage in the fixing hole of the fixing portion.

13. The assembly of claim 12, wherein the thermal module further comprises a fan mounted to the heat sink.

14. The assembly of claim 10, wherein each frame comprises a pivoting portion and two arms extending from opposite sides of the pivoting portion, the pivoting portion defines a pivot hole pivotably fitting about the pivoting portion, the slot is defined in each arm.

15. The assembly of claim 14, wherein the arms are substantially bar-shaped, the slots are longitudinally defined in the corresponding arms.

16. The assembly of claim 14, wherein the fixing portion is substantially column-shaped, and the pivoting portion is substantially circular-shaped.
